(19) United States
(12) Patent Application Publication
(10) Pub. No.: US 2024/0204055 A1
(43) Pub. Date: Jun. 20, 2024

(54) SCREEN LAYER INTEGRATION IN GALLIUM NITRIDE TECHNOLOGY

(71) Applicant: Texas Instruments Incorporated, Dallas, TX (US)

(72) Inventor: Dong Seup Lee, McKinney, TX (US)

(21) Appl. No.: 18/067,705

(22) Filed: Dec. 17, 2022

(51) Int. Cl. H01L 29/10; H01L 21/265; H01L 21/266; H01L 21/74; H01L 29/20; H01L 29/205; H01L 29/66; H01L 29/778

(52) U.S. Cl. CPC H01L 29/1075; H01L 21/26546; H01L 21/266; H01L 21/743; H01L 21/746; H01L 29/2003; H01L 29/205; H01L 29/66462; H01L 29/7786

(57) ABSTRACT

A microelectronic device includes a lower buffer layer of III-N semiconductor material formed over a silicon substrate. A screen layer having free charge carriers is formed over the lower buffer layer. The microelectronic device may include an upper buffer layer of III-N semiconductor material formed over the screen layer. A gallium nitride field effect transistor (GaN FET) is formed over the screen layer. The GaN FET has a two-dimensional electron gas (2DEG) layer directly over at least a portion of the screen layer. The screen layer may include a doped layer of III-N semiconductor material, or a buried barrier layer with 2DEG layers in the lower and upper buffer layers. The screen layer is electrically connected to a current node, that is, a source node or a drain node, of the GaN FET.

### TECHNICAL FIELD

This disclosure relates to the field of microelectronic devices that include gallium nitride. More particularly, but not exclusively, this disclosure relates to screen layers in microelectronic devices that include gallium nitride.

### BACKGROUND

Microelectronic devices that includes gallium nitride components may have semiconductor substrates, such as silicon substrates, below the gallium nitride components. The gallium nitride components, such as field effect transistors, may include mobile charge layers, commonly referred to as two-dimensional electron gas (2DEG) layers. The gallium nitride components may be operated at potentials significantly above substrate potentials applied to the semiconductor substrates. The mobile charge layers may be depleted by the potential differences, reducing performance of the gallium nitride components.

### SUMMARY

The present disclosure introduces a microelectronic device that includes a silicon substrate and a lower buffer layer of III-N semiconductor material over the silicon substrate. The microelectronic device includes a screen layer having free charge carriers over the lower buffer layer. The microelectronic device includes a field effect transistor having III-N semiconductor material over the screen layer. The screen layer is electrically connected to a current node of the field effect transistor. Example methods of forming the screen layer are disclosed.

### BRIEF DESCRIPTION OF THE VIEWS OF THE DRAWINGS

FIG. 1 is a cross section of an example microelectronic device with a screen layer.

FIG. 2A through FIG. 2C are cross sections of the microelectronic device of FIG. 1, depicted in successive stages of an example method of formation.

FIG. 3 is a cross section of another example microelectronic device with a screen layer.

FIG. 4A and FIG. 4B are cross sections of the microelectronic device of FIG. 3, depicted in successive stages of an example method of formation.

FIG. 5 is a cross section of another example microelectronic device with a screen layer.

FIG. 6A through FIG. 6C are cross sections of the microelectronic device of FIG. 5, depicted in successive stages of an example method of formation.

FIG. 7A through FIG. 7C are cross sections of the microelectronic device of FIG. 5, depicted in an alternate example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A microelectronic device includes a silicon substrate and a lower buffer layer of III-N semiconductor material formed over the silicon substrate. The microelectronic device includes a screen layer having free charge carriers over the lower buffer layer. The microelectronic device may include an upper buffer layer of III-N semiconductor material formed over the screen layer. The microelectronic device further includes a field effect transistor that includes III-N semiconductor material over the screen layer. The field effect transistor has a two-dimensional electron gas (2DEG) layer directly over at least a portion of the screen layer. The screen layer is electrically connected to a current node, that is, a source node or a drain node, of the field effect transistor. During operation of the microelectronic device, the screen layer may shield the 2DEG layer from a potential on the silicon substrate, thereby reducing depletion of the 2DEG layer and thus advantageously improving an on-state resistance of the field effect transistor.

For the purposes of this description, the term “III-N semiconductor material” is understood to refer to semiconductor materials in which group III elements, that is, aluminum, gallium, and indium, and possibly boron, provide a portion of the atoms in the semiconductor material and nitrogen atoms provide another portion of the atoms in the semiconductor material. Examples of III-N semiconductor materials are gallium nitride, boron gallium nitride, aluminum gallium nitride, indium nitride, and indium aluminum gallium nitride. For the purposes of this description, the term GaN FET is understood to refer to a field effect transistor which includes III-N semiconductor materials, and not necessarily exclusively gallium nitride.

It is noted that terms such as top, over, above, under, and below may be used in this disclosure. These terms should not be construed as limiting the position or orientation of a structure or element, but should be used to provide spatial relationship between structures or elements. For the purposes of this disclosure, the term “laterally” refers to a direction parallel to a plane of the instant top surface of the III-N semiconductor material.

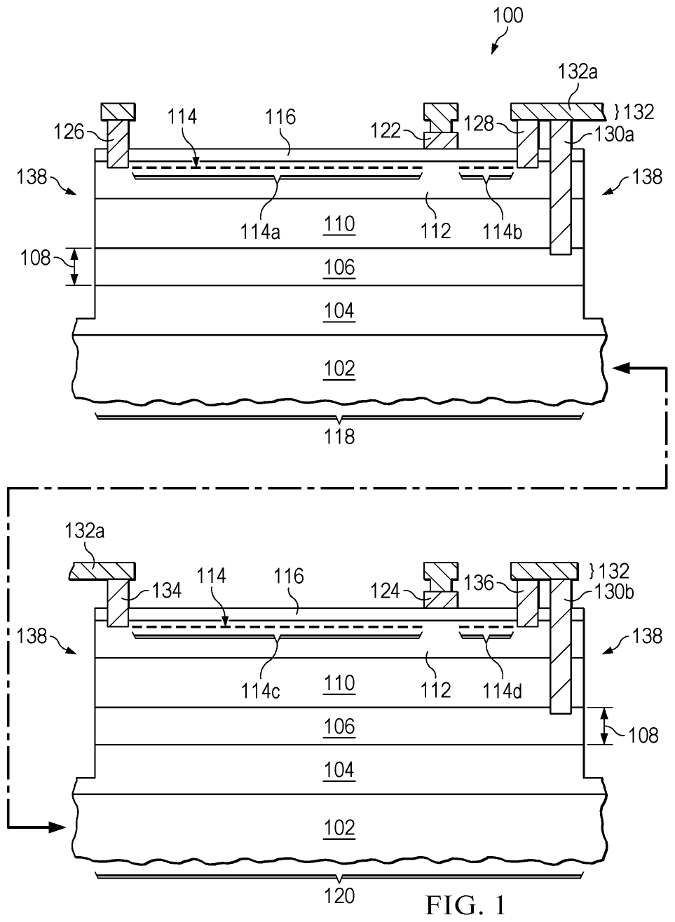

FIG. 1 is a cross section of an example microelectronic device with a screen layer. The microelectronic device 100 has a silicon substrate 102. The silicon substrate 102 is monocrystalline, and may have a (111) crystal orientation, to facilitate epitaxial growth of III-N semiconductor material. The silicon substrate 102 may be part of a silicon wafer, by way of example.

The microelectronic device 100 includes a lower buffer layer 104 of III-N semiconductor material over the silicon substrate 102. The lower buffer layer 104 may include a nucleation sublayer, not specifically shown, of aluminum nitride on the silicon substrate 102. The aluminum nitride has a lattice constant close to silicon's lattice constant, which may advantageously enable epitaxial growth of a low defect III-N semiconductor material on the silicon substrate 102. The lower buffer layer 104 may include one or more transition sublayers, not specifically shown, of aluminum gallium nitride with increasing gallium content, on the nucleation sublayer. The lower buffer layer 104 may further include a lower unintentionally doped (UID) sublayer, not specifically shown, of primarily gallium nitride on the one or more transition sublayers. The lower buffer layer 104 may be 1 micron to 10 microns, depending on an operational potential of active components in the microelectronic device 100. Other structures and compositions for the lower buffer layer 104 are within the scope of this example.

The microelectronic device 100 includes a screen layer 106 of III-N semiconductor material over the lower buffer layer 104. In this example, the III-N semiconductor material of the screen layer 106 is doped with first conductivity type dopants, and so has free carriers, and has the first conductivity type. The III-N semiconductor material may consist primarily of gallium nitride and the dopants. In one version of this example, the first conductivity type may be p-type so that the free carriers are holes, and the first conductivity type dopants may include magnesium. In another version of this example, the first conductivity type may be n-type so that the free carriers are electrons, and the first conductivity type dopants may include silicon or germanium. Other dopants for the screen layer 106 are within the scope of this example. An average dopant density in the screen layer 106 may be 1×10¹⁶ cm⁻³ to 1×10²¹ cm⁻³, by way of example. During operation of the microelectronic device 100, the screen layer 106 may be partially depleted due to a potential difference between the silicon substrate 102 and a 2DEG layer above the screen layer 106. A thickness 108 of the screen layer 106 is sufficiently large that a portion of the free carriers remain in the screen layer 106 when the screen layer 106 is partially depleted. The thickness 108 may be 10 nanometers to 3 microns, by way of example. In this example, the screen layer 106 may extend across the microelectronic device 100, as indicated in FIG. 1.

The microelectronic device 100 may optionally include an upper buffer layer 110 over the screen layer 106. The upper buffer layer 110 may consist primarily of UID gallium nitride. The upper buffer layer 110 may be 100 nanometers to 10 microns thick, for example, and may provide a transition from the screen layer 106 to active components in the microelectronic device 100.

The microelectronic device 100 includes an undoped layer 112 of III-N semiconductor material that supports a 2DEG layer 114. The undoped layer 112 may be primarily undoped gallium nitride. The 2DEG layer 114 may have an electron density of 1×10¹² cm⁻² to 1×10¹⁵ cm⁻², by way of example. The 2DEG layer 114 extends directly over at least a portion of the screen layer 106. The screen layer 106 and the 2DEG layer 114 may both extend across the microelectronic device 100, as indicated in FIG. 1.

The microelectronic device 100 includes a barrier layer 116 of III-N semiconductor material on the undoped layer 112. The barrier layer 116 has a higher bandgap energy than the undoped layer 112. The barrier layer 116 causes the conduction band off the undoped layer 112 to be bent below the Fermi level, producing the 2DEG layer 114. The barrier layer 116 may be substantially homogeneous and include primarily aluminum nitride, aluminum gallium nitride, or other III-N semiconductor material having a higher bandgap energy than the undoped layer 112. Alternatively, the barrier layer 116 may include sublayers of different compositions, such as a sublayer of aluminum nitride on the undoped layer 112 and a sublayer of aluminum gallium nitride on the sublayer of aluminum nitride. The barrier layer 116 may be 2 nanometers to 30 nanometers thick, by way of example. A composition and thickness of the barrier layer 116 may be selected to provide a desired electron density in the 2DEG layer 114.

In this example, the microelectronic device 100 includes a half-bridge stage containing a high side gallium nitride field effect transistor (GaN FET) 118 connected to a low side GaN FET 120. The high side GaN FET 118 includes a high side gate 122 over the barrier layer 116. The low side GaN FET 120 includes a low side gate 124 over the barrier layer 116. The high side gate 122 and the low side gate 124 may include primarily p-type gallium nitride, by way of example, so that the high side GaN FET 118 and the low side GaN FET 120 are enhancement mode transistors, commonly referred to as normally-off transistors. Other compositions for the high side gate 122 and the low side gate 124 are within the scope of this example.

The high side GaN FET 118 includes a high side drain contact 126 that makes an electrical connection to the 2DEG layer 114. The high side GaN FET 118 includes a high side source contact 128 that makes an electrical connection to the 2DEG layer 114 opposite from the high side drain contact 126. The high side gate 122 is located between the high side drain contact 126 and the high side source contact 128. The 2DEG layer 114 includes a high side drain access region 114a which extends between the high side drain contact 126 and the high side gate 122. The 2DEG layer 114 includes a high side source access region 114b which extends between the high side source contact 128 and the high side gate 122.

The high side GaN FET 118 includes a high side screen contact 130a that makes an electrical connection to the screen layer 106 under the high side GaN FET 118. The high side screen contact 130a is electrically connected to the high side source contact 128. The high side screen contact 130a and the high side source contact 128 may be connected through a member 132a of an interconnect level 132 of the microelectronic device 100.

The low side GaN FET 120 includes a low side drain contact 134 that makes an electrical connection to the 2DEG layer 114. The low side GaN FET 120 includes a low side source contact 136 that makes an electrical connection to the 2DEG layer 114 opposite from the low side drain contact 134. The low side GaN FET 120 may further include an optional low side screen contact 130b that makes an electrical connection to the screen layer 106 under the low side GaN FET 120. When the screen layer 106 under the low side GaN FET 120 is connected to the low side source contact 136, the screen layer 106 under the low side GaN FET 120 must be isolated from the screen layer 106 under the high side GaN FET 118, for example by isolation regions 138 such as isolation trenches, as indicated schematically in FIG. 1. The low side gate 124 is located between the low side drain contact 134 and the low side source contact 136. The 2DEG layer 114 includes a low side drain access region 114c which extends between the low side drain contact 134 and the low side gate 124. The 2DEG layer 114 includes a low side source access region 114d which extends between the low side source contact 136 and the low side gate 124. The low side drain contact 134 is electrically connected to the high side source contact 128 to provide the half-bridge stage. The low side drain contact 134 and the high side source contact 128 may be connected through the member 132a of the interconnect level 132. The high side GaN FET 118 and the low side GaN FET 120 may be laterally separated by the isolation regions 138.

The high side drain contact 126, the high side source contact 128, the high side screen contact 130a, the low side drain contact 134, the low side drain contact 134, and the low side screen contact 130b are electrically conductive, and may include an adhesion layer of titanium or titanium tungsten, and a fill layer of aluminum, by way of example. Source/drain contact holes for the high side drain contact 126, the high side source contact 128, the low side drain contact 134, and the low side drain contact 134 may be etched concurrently through the barrier layer 116 to the 2DEG layer 114. Screen contact holes for the high side screen contact 130a and the low side screen contact 130b may be etched concurrently through the barrier layer 116, the undoped layer 112, and the upper buffer layer 110, to the screen layer 106. Subsequently, the adhesion layer may be formed in the source/drain contact holes and the screen contact holes by a first physical deposition process, and the fill layer may be formed on the adhesion layer by a second physical deposition process. The fill layer and the adhesion layer may be patterned using an etch mask and a reactive ion etch (RIE) process.

During operation of the microelectronic device 100, the high side drain contact 126 may be connected to a voltage supply at bias potential, and the low side source contact 136 may be connected to a ground node at a ground potential. The silicon substrate 102 may also be connected to the ground node. The bias potential may be 10 volts to 300 volts above the ground potential, by way of example. The high side GaN FET 118 and the low side GaN FET 120 may be alternately turned on and off by appropriate signals to the high side gate 122 and the low side gate 124, so that the low side GaN FET 120 is off when the high side GaN FET 118 is on, and vice versa. An on-state resistance of the high side GaN FET 118 is primarily determined by an electron density in the high side drain access region 114a.

When the high side GaN FET 118 is off, the low side GaN FET 120 is on, and so the low side drain contact 134 is connected to the low side source contact 136 through the low side source access region 114d, a low side channel region, not specifically shown, under the low side gate 124 and the low side drain access region 114c, so that the low side drain contact 134 is at the ground potential. The high side source contact 128, being connected to the low side drain contact 134, is also at the ground potential. The screen layer 106 under the high side GaN FET 118, being connected to the high side source contact 128 through the high side screen contact 130a, is also at the ground potential. The screen layer 106 under the low side GaN FET 120, being connected to the low side source contact 136 through the low side screen contact 130b, is always at the ground potential.

When the high side GaN FET 118 is turned on, the low side GaN FET 120 is off, and so the high side source contact 128 is connected to the high side drain contact 126 through the high side source access region 114b, a high side channel, not specifically shown, under the high side gate 122, and the high side drain access region 114a, so that the high side source contact 128 rises to the bias potential. The screen layer 106, being connected to the high side source contact 128, also rises to the bias potential. The screen layer 106, being at the bias potential, screens the high side drain access region 114a from the silicon substrate 102, reducing depletion of the high side drain access region 114a, advantageously reducing the on-state resistance of the high side GaN FET 118.

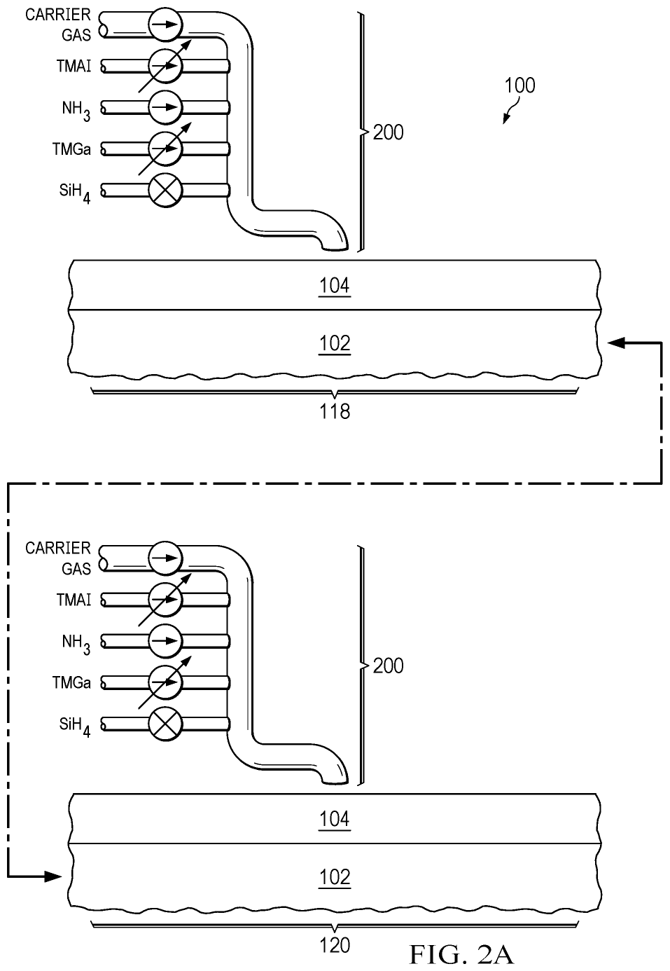

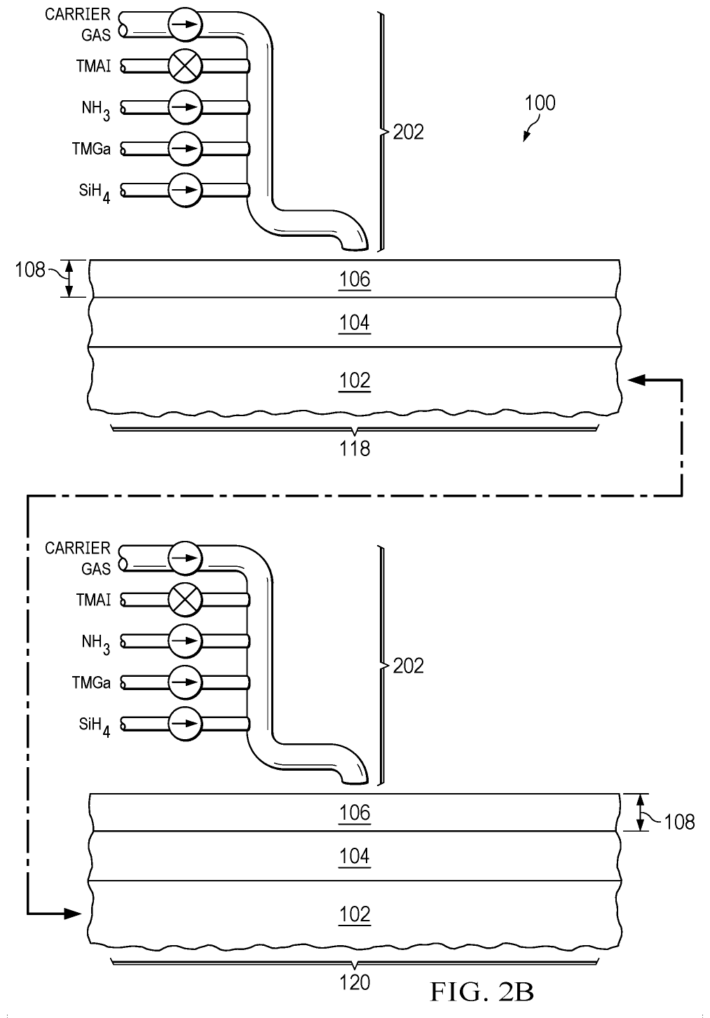

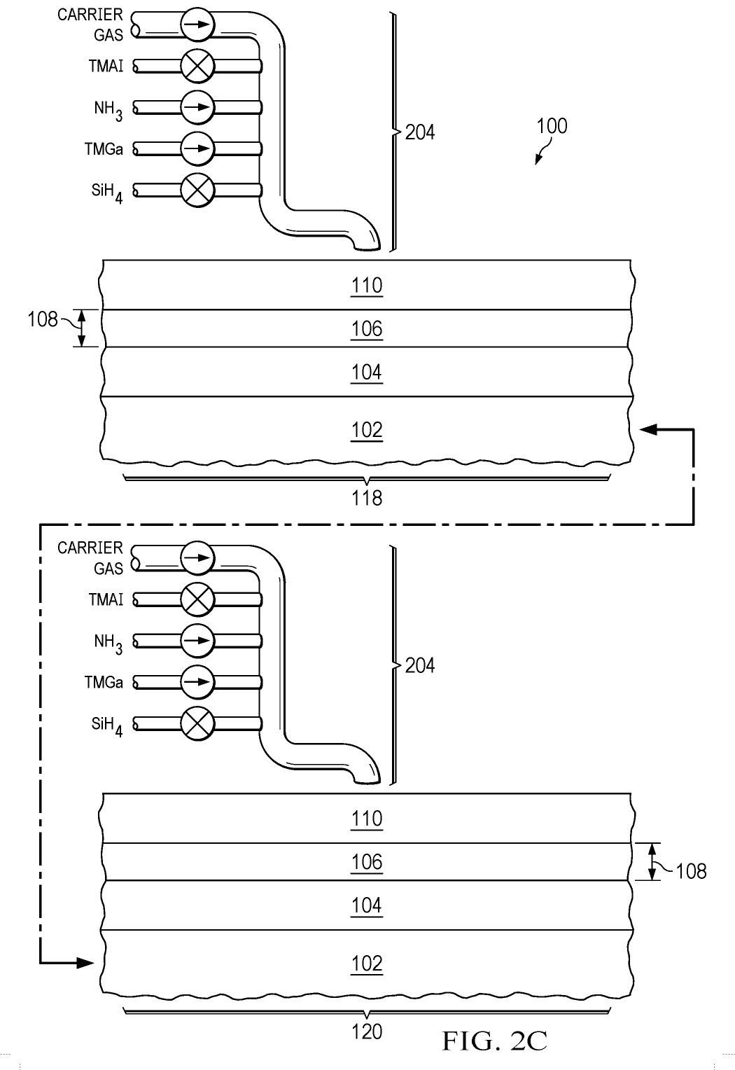

FIG. 2A through FIG. 2C are cross sections of the microelectronic device 100 of FIG. 1, depicted in successive stages of an example method of formation. Referring to FIG. 2A, the lower buffer layer 104 is formed over the silicon substrate 102 by a first metal organic vapor phase epitaxy (MOVPE) process 200. The first MOVPE process 200 initially delivers an aluminum-containing reagent, such as trimethyl aluminum, labeled “TMAI” in FIG. 2A, and a nitrogen-containing reagent, such as ammonia, labeled “NH₃” in FIG. 2A, in a carrier gas, labeled “CARRIER GAS” in FIG. 2A, to the silicon substrate 102. The carrier gas may include hydrogen, nitrogen, argon, or any combination thereof. The first MOVPE process 200 forms a nucleation sublayer of aluminum nitride on the silicon substrate 102. The first MOVPE process 200 subsequently delivers increasing amounts of a gallium-containing reagent, such as trimethyl gallium, labeled “TMGa” in FIG. 2A and decreasing amounts of the aluminum-containing reagent, along with the nitrogen-containing reagent, to form one or more transition sublayers of III-N semiconductor material with increasing gallium content on the nucleation sublayer. The first MOVPE process 200 finally delivers the gallium-containing reagent and the nitrogen-containing reagent, with none of the aluminum-containing reagent, to form a lower UID sublayer of gallium nitride on the one or more transition sublayers.

Referring to FIG. 2B, the screen layer 106 is formed over the lower buffer layer 104 by a second MOVPE process 202. The second MOVPE process 202 delivers the gallium-containing reagent and the nitrogen-containing reagent, along with a dopant-containing reagent, such as silane, labeled “SiH₄” in FIG. 2B, or disilane in the carrier gas, to the lower buffer layer 104. The silane provides the n-type dopant silicon in the screen layer 106, so that the screen layer 106 has n-type conductivity. In an alternate version of this example, the dopant-containing reagent may be implemented as bis cyclopentadienyl magnesium, which provides the p-type dopant magnesium in the screen layer 106, so that the screen layer 106 has p-type conductivity. Other dopant-containing reagents are within the scope of this example.

Referring to FIG. 2C, the upper buffer layer 110 is formed over the screen layer 106 by a third MOVPE process 204. The third MOVPE process 204 delivers the gallium-containing reagent and the nitrogen-containing reagent to form the upper buffer layer 110.

Forming the screen layer 106 using the second MOVPE process 202 between the first MOVPE process 200 and the third MOVPE process 204 may advantageously reduce fabrication cost and complexity of the microelectronic device 100. Concentration of the dopants in the screen layer 106 and the thickness 108 of the screen layer 106 may be adjusted for the particular bias potential of the high side GaN FET 118. Forming the screen layer 106 using the second MOVPE process 202 advantageously enables use of a commercially available silicon substrate 102, eliminating a requirement for a custom substrate with a screen layer.

Formation of the microelectronic device 100 continues with forming the barrier layer 116 of FIG. 1. The isolation regions 138 of FIG. 1 may be formed after the III-N semiconductor layers are formed.

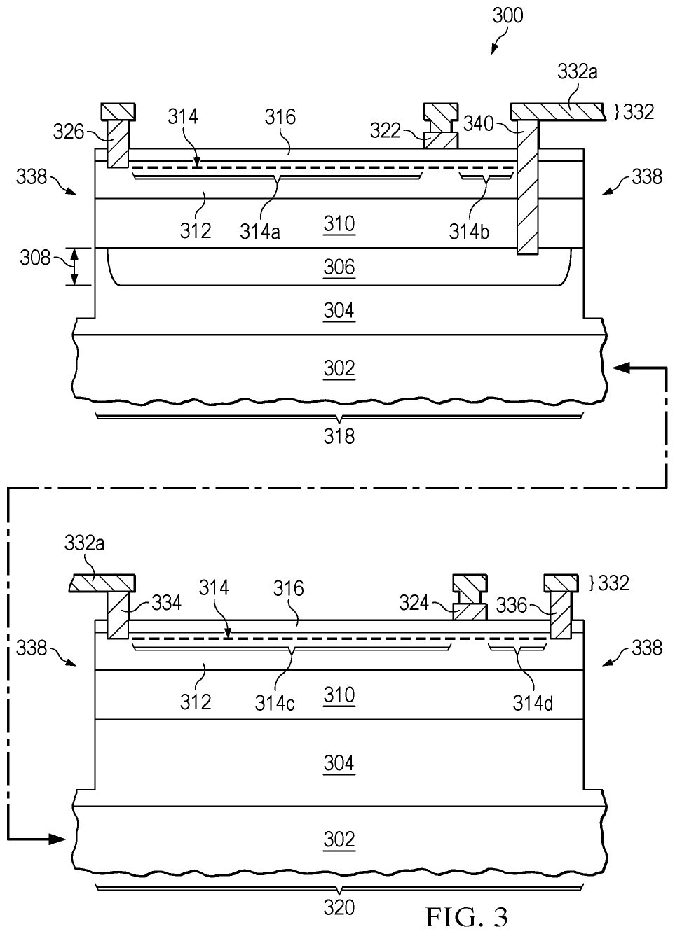

FIG. 3 is a cross section of another example microelectronic device with a screen layer. The microelectronic device 300 has a silicon substrate 302 with a lower buffer layer 304 of III-N semiconductor material over the silicon substrate 302. The lower buffer layer 304 may have a structure and composition similar to the lower buffer layer 104 of FIG. 1.

In this example, the microelectronic device 300 includes a half-bridge stage containing a high side GaN FET 318 connected to a low side GaN FET 320. The microelectronic device 300 includes a screen layer 306 of III-N semiconductor material over the lower buffer layer 304 under the high side GaN FET 318. The screen layer 306 may be localized to the area under the high side GaN FET 318, as depicted in FIG. 3. In this example, the III-N semiconductor material of the screen layer 306 is doped with first conductivity type dopants, and so has free carriers, and has the first conductivity type. The screen layer 306 of this example may have a similar composition to the lower buffer layer 304 with the addition of the first conductivity type dopants. The first conductivity type dopants may be p-type dopants or may be n-type dopants. An average dopant density and thickness 308 of the screen layer 306 may be similar to the screen layer 106 of FIG. 1. In an alternate version of this example, the screen layer 306 may extend across the microelectronic device 300.

The microelectronic device 300 may optionally include an upper buffer layer 310 over the screen layer 306 under the high side GaN FET 318, and over the lower buffer layer 304 under the low side GaN FET 320. The upper buffer layer 310 may consist primarily of UID gallium nitride.

The microelectronic device 300 includes an undoped layer 312 of III-N semiconductor material over the upper buffer layer 310. The undoped layer 312 supports a 2DEG layer 314. The undoped layer 312 may be primarily undoped gallium nitride. The 2DEG layer 314 may have an electron density as disclosed in reference to the 2DEG layer 114 of FIG. 1. The 2DEG layer 314 extends directly over at least a portion of the screen layer 306.

The microelectronic device 300 includes a barrier layer 316 of III-N semiconductor material on the undoped layer 312. The barrier layer 316 has a higher bandgap energy than the undoped layer 312, and produces the 2DEG layer 314. The barrier layer 316 may have any of the structures and compositions disclosed in reference to the barrier layer 116 of FIG. 1.

The high side GaN FET 318 includes a high side gate 322 over the barrier layer 316. The low side GaN FET 320 includes a low side gate 324 over the barrier layer 316. The high side gate 322 and the low side gate 324 may include metal such as titanium tungsten, by way of example, so that the high side GaN FET 318 and the low side GaN FET 320 are depletion mode transistors, commonly referred to as normally-on transistors. Other compositions for the high side gate 322 and the low side gate 324 are within the scope of this example.

The high side GaN FET 318 includes a high side drain contact 326 that makes an electrical connection to the 2DEG layer 314. The high side GaN FET 318 includes a high side combined source/screen contact 340 that makes an electrical connection to the 2DEG layer 314 opposite from the high side drain contact 326 and makes an electrical connection to the screen layer 306. The combined source/screen contact 340 may advantageously consume less area than separate contacts to the 2DEG layer 314 and to the screen layer 306. The high side gate 322 is located between the high side drain contact 326 and the high side combined source/screen contact 340. The 2DEG layer 314 includes a high side drain access region 314a which extends between the high side drain contact 326 and the high side gate 322. The 2DEG layer 314 includes a high side source access region 314b which extends between the high side combined source/screen contact 340 and the high side gate 322.

The low side GaN FET 320 includes a low side drain contact 334 that makes an electrical connection to the 2DEG layer 314, and a low side source contact 336 that makes an electrical connection to the 2DEG layer 314 opposite from the low side drain contact 334. The low side gate 324 is located between the low side drain contact 334 and the low side source contact 336. The 2DEG layer 314 includes a low side drain access region 314c which extends between the low side drain contact 334 and the low side gate 324, and includes a low side source access region 314d which extends between the low side source contact 336 and the low side gate 324. The low side drain contact 334 is electrically connected to the high side combined source/screen contact 340 to provide the half-bridge stage. The low side drain contact 334 and the high side combined source/screen contact 340 may be connected through a member 332a of an interconnect level 332 of the microelectronic device 300. The high side GaN FET 318 and the low side GaN FET 320 may be laterally separated by isolation regions 338, as indicated schematically in FIG. 3.

Operation of the microelectronic device 300 may proceed as disclosed for the microelectronic device 100 of FIG. 1, in which the screen layer 306 screens the high side drain access region 314a from the silicon substrate 302, reducing depletion of the high side drain access region 314a, thus advantageously reducing the on-state resistance of the high side GaN FET 318.

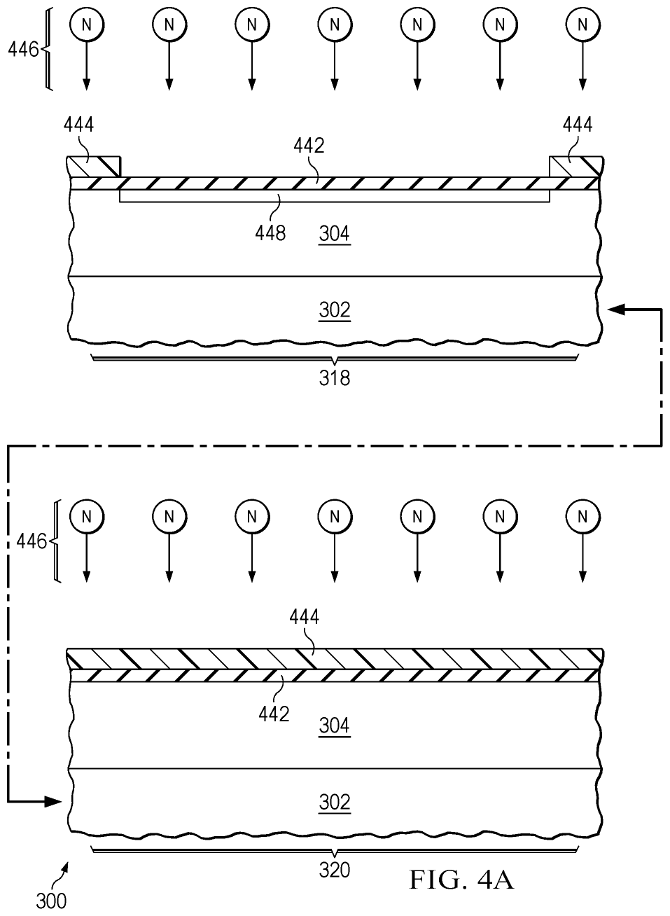

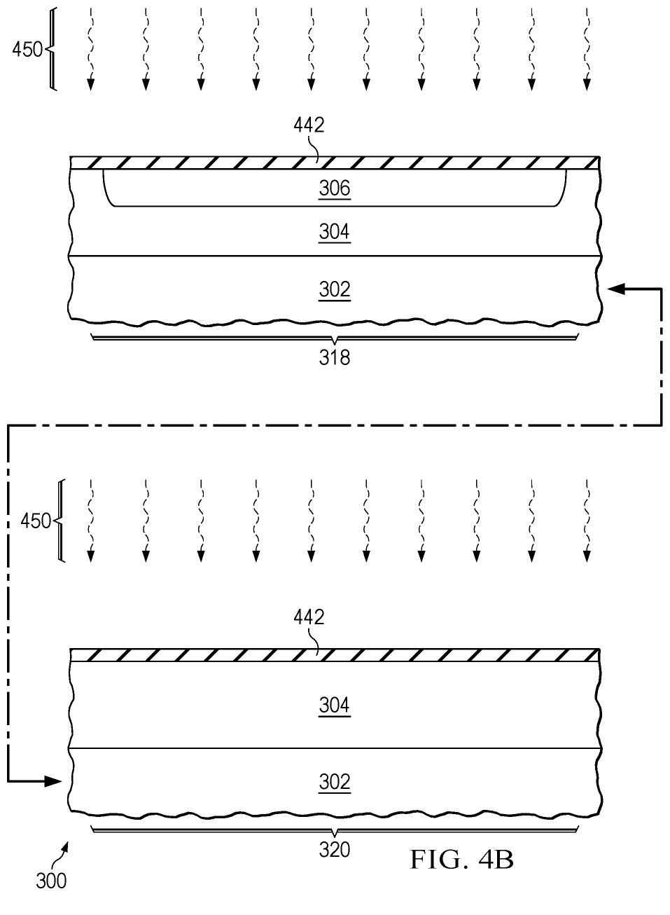

FIG. 4A and FIG. 4B are cross sections of the microelectronic device 300 of FIG. 3, depicted in successive stages of an example method of formation. Referring to FIG. 4A, the lower buffer layer 304 is formed over the silicon substrate 302. The lower buffer layer 304 may be formed by an MOVPE process, as disclosed in reference to FIG. 2A. In this example, the lower buffer layer 304 is formed sufficiently thick to accommodate the screen layer 306 of FIG. 3.

A protective layer 442 is formed over the lower buffer layer 304 to reduce degradation of the lower buffer layer 304 during subsequent fabrication steps. The protective layer 442 may include silicon dioxide, formed by a plasma enhanced chemical vapor deposition (PECVD) process using tetraethyl orthosilicate (TEOS), formally named tetraethoxysilane. Alternatively, the protective layer 442 may include silicon nitride, formed by a low pressure chemical vapor deposition (LPCVD) process using dichlorosilane and ammonia. The protective layer 442 may be 2 nanometers to 20 nanometers thick, by way of example. Other compositions and processes for the protective layer 442 are within the scope of this example.

An implant mask 444 is formed over the protective layer 442. The implant mask 444 exposes an area for the screen layer 306 of FIG. 3. In this example, the implant mask 444 covers the protective layer 442 and the underlying lower buffer layer 304 in an area for the low side GaN FET 320. The implant mask 444 may include photoresist, and may be formed by a photolithographic process. The implant mask 444 may include hard mask material, such as silicon dioxide.

Dopants 446 are implanted into the lower buffer layer 304 where exposed by the implant mask 444 to form a screen implanted region 448. The dopants 446 may be n type dopants such as silicon or germanium, as indicated schematically in FIG. 4A, or p type dopants, such as magnesium. The dopants 446 are implanted at a total dose sufficient to provide effective screening of the high side drain access region 314a of FIG. 3. The dopants 446 may be implanted at a total dose that is 100 percent to 200 percent of an electron density in the high side drain access region 314a. By way of example, the dopants 446 may be implanted at a total dose of 1×10¹² cm⁻² to 2×10¹⁵ cm⁻². adjust for corrected density

After the dopants 446 are implanted, the implant mask 444 is removed. Photoresist in the implant mask 444 may be removed by exposure to oxygen radicals, such as an asher process, followed by a wet clean process using an aqueous mixture of hydrogen peroxide and ammonium hydroxide. Hard mask material in the implant mask 444 may be removed by etching in an aqueous solution of dilute buffered hydrofluoric acid.

Referring to FIG. 4B, the lower buffer layer 304 is heated to 1200° C. to 1250° C. in nitrogen gas for 20 minutes to 40 minutes, to anneal the III-N semiconductor material in the screen implanted region 448 of FIG. 4A, and diffuse and activate the implanted dopants, forming the screen layer 306. The lower buffer layer 304 may be heated by a radiant heating process 450, as indicated schematically in FIG. 4B. Alternatively, the lower buffer layer 304 may be heated by a furnace process.

Forming the screen layer 306 to be localized under the high side GaN FET 318 may advantageously improve performance of the high side GaN FET 318 without affecting performance of the low side GaN FET 320 or other components in the microelectronic device 300.

After the lower buffer layer 304 is heated, the protective layer 442 is removed. Silicon dioxide in the protective layer 442 may be removed using an aqueous solution of dilute buffered hydrofluoric acid. Silicon nitride in the protective layer 442 may be removed using an aqueous solution of activated phosphoric acid at 140° C.

After the protective layer 442 is removed, formation of the microelectronic device 300 continues with forming the upper buffer layer 310. A thickness of the upper buffer layer 310 may be selected to ameliorate defects in the screen layer 306 resulting from the implantation of the dopants 446 of FIG. 4A and the subsequent heating to diffuse and activate the dopants 446.

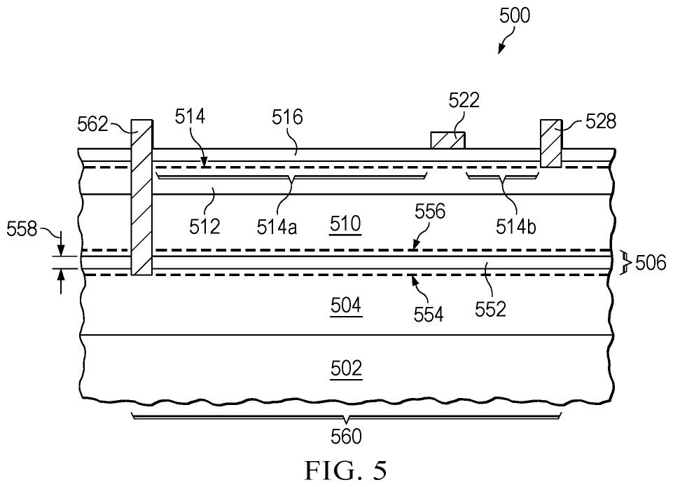

FIG. 5 is a cross section of another example microelectronic device with a screen layer. The microelectronic device 500 has a silicon substrate 502 with a lower buffer layer 504 of III-N semiconductor material over the silicon substrate 502. The microelectronic device 500 includes an upper buffer layer 510 of III-N semiconductor material above the lower buffer layer 504. The lower buffer layer 504 and the upper buffer layer 510 may have structures and compositions similar to the lower buffer layer 104 and the upper buffer layer 110 of FIG. 1.

In this example, the screen layer 506 includes a buried barrier layer 552 of III-N semiconductor material between the lower buffer layer 504 and the upper buffer layer 510. The buried barrier layer 552 has a higher bandgap energy than the lower buffer layer 504, and has a higher bandgap energy than the upper buffer layer 510. The buried barrier layer 552 may include primarily aluminum nitride, by way of example. Other compositions for the buried barrier layer 552 are within the scope of this example. The buried barrier layer 552 causes the conduction band off the lower buffer layer 504 to be bent below the Fermi level, producing a lower 2DEG layer 554 of the screen layer 506 in the lower buffer layer 504 adjacent to the buried barrier layer 552.

In one version of this example, the buried barrier layer 552 may cause the conduction band of the upper buffer layer 510 to be bent below the Fermi level, producing an upper charge layer 556, manifested as a 2DEG layer, of the screen layer 506 in the upper buffer layer 510 adjacent to the buried barrier layer 552. In another version of this example, the buried barrier layer 552 may cause the valence band of the upper buffer layer 510 to cross the Fermi level, producing an upper charge layer 556, manifested as a two-dimensional hole gas (2DHG) layer, of the screen layer 506 in the upper buffer layer 510 adjacent to the buried barrier layer 552. In a further version of this example, neither the conduction band nor the valence band of the upper buffer layer 510 crosses the Fermi level, so that no upper charge layer is formed in the upper buffer layer 510.

The lower 2DEG layer 554 and the upper charge layer 556, if formed, provide free carriers in the screen layer 506. A thickness 558 of the buried barrier layer 552 and a composition of the buried barrier layer 552 may be selected to produce a desired total charge density in the lower 2DEG layer 554 and the upper charge layer 556.

The microelectronic device 500 includes undoped layer 512 of III-N semiconductor material over the upper buffer layer 510, and a barrier layer 516 of III-N semiconductor material on the undoped layer 512. The barrier layer 516 has a higher bandgap energy than the undoped layer 512, and produces a 2DEG layer 514 in the undoped layer 512. The undoped layer 512 and the barrier layer 516 may have any of the structures and compositions disclosed in reference to the undoped layer 112 and the barrier layer 116 of FIG. 1.

The microelectronic device 500 includes a GaN FET 560 over the screen layer 506. The GaN FET 560 includes a gate 522 over the barrier layer 516. The microelectronic device 500 includes a source contact 528 that makes an electrical connection to the 2DEG layer 514.

The microelectronic device 500 of this example includes a combined drain/screen contact 562 that makes an electrical connection to the 2DEG layer 514 and makes electrical connections to the lower 2DEG layer 554 and the upper charge layer 556, if formed. The gate 522 is located between the source contact 528 and the combined drain/screen contact 562.

The 2DEG layer 514 includes a drain access region 514a which extends between the combined drain/screen contact 562 and the gate 522. The 2DEG layer 514 includes a source access region 514b which extends between the source contact 528 and the gate 522.

During operation of the microelectronic device 500, the lower 2DEG layer 554 and the upper charge layer 556 are biased to a bias potential applied to the combined drain/screen contact 562, whether the GaN FET 560 is in an on state or in an off state. The drain access region 514a and the source access region 514b are thus shielded from the silicon substrate 502, which may advantageously improve a transition time for the GaN FET 560 from the off state to the on state, as well as improve an on-state resistance of the GaN FET 560.

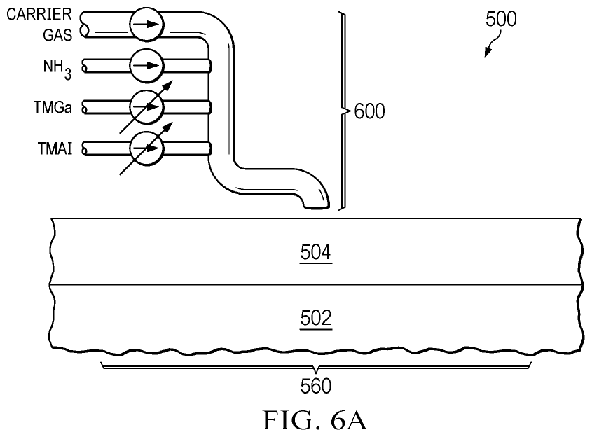

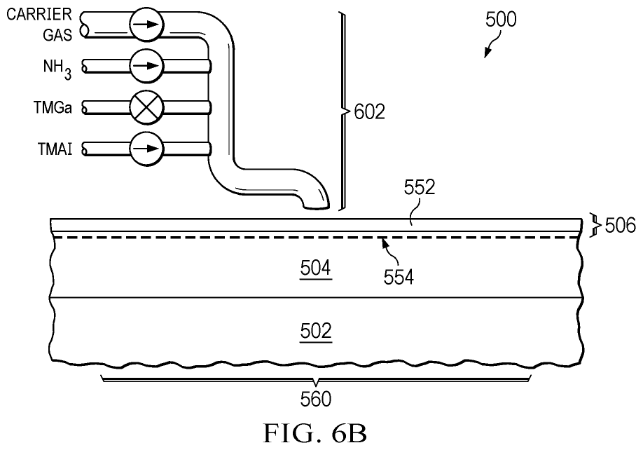

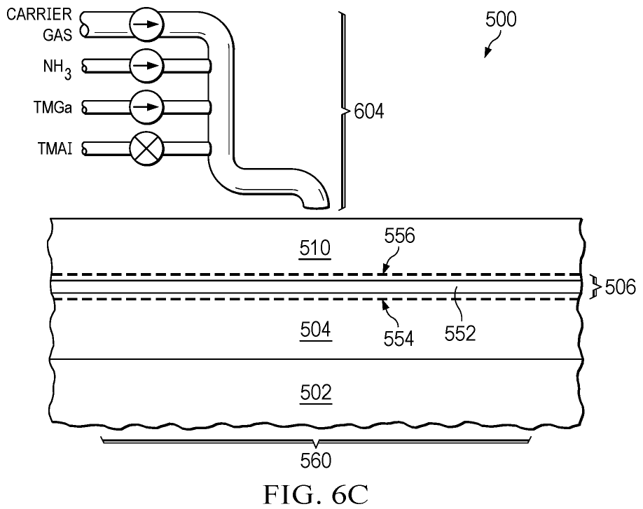

FIG. 6A through FIG. 6C are cross sections of the microelectronic device 500 of FIG. 5, depicted in successive stages of an example method of formation. Referring to FIG. 6A, the lower buffer layer 504 is formed over the silicon substrate 502. The lower buffer layer 504 may be formed by a first MOVPE process 600, for example, as disclosed in reference to FIG. 2A. The first MOVPE process 600 may form an aluminum nitride nucleation layer on the silicon substrate using an aluminum-containing reagent and a nitrogen-containing reagent, followed by one or more transition sublayers of III-N semiconductor material with increasing gallium content on the nucleation sublayer, using the aluminum-containing reagent, a gallium-containing reagent, and the nitrogen-containing reagent. The first MOVPE process 600 may subsequently form a lower UID sublayer of gallium nitride on the one or more transition sublayers, using the gallium-containing reagent and the nitrogen-containing reagent.

Referring to FIG. 6B, the buried barrier layer 552 of the screen layer 506 is formed on the lower buffer layer 504 by a second MOVPE process 602. In one version of this example, the buried barrier layer 552 may include essentially aluminum nitride, and the second MOVPE process 602 may form the buried barrier layer 552 using the aluminum-containing reagent and the nitrogen-containing reagent. In another version of this example, the buried barrier layer 552 may include aluminum gallium nitride, and the second MOVPE process 602 may form the buried barrier layer 552 using the aluminum-containing reagent, the gallium-containing reagent, and the nitrogen-containing reagent. As the buried barrier layer 552 is formed by the second MOVPE process 602, the lower 2DEG layer 554 of the screen layer 506 is formed in the lower buffer layer 504 adjacent to the buried barrier layer 552.

Referring to FIG. 6C, the upper buffer layer 510 is formed on the buried barrier layer 552 by a third MOVPE process 604. The third MOVPE process 604 delivers the gallium-containing reagent and the nitrogen-containing reagent to form the upper buffer layer 510. As the upper buffer layer 510 is formed on the buried barrier layer 552, the upper charge layer 556 of the screen layer 506 may be formed in the upper buffer layer 510 adjacent to the buried barrier layer 552. Formation of the microelectronic device 500 continues with forming the barrier layer 516 of FIG. 5.

Forming the screen layer 506 using the second MOVPE process 602 to form the buried barrier layer 552 between the lower buffer layer 504 and the upper buffer layer 510 may advantageously reduce fabrication cost and complexity of the microelectronic device 100, and may advantageously enable use of a commercially available silicon substrate 502.

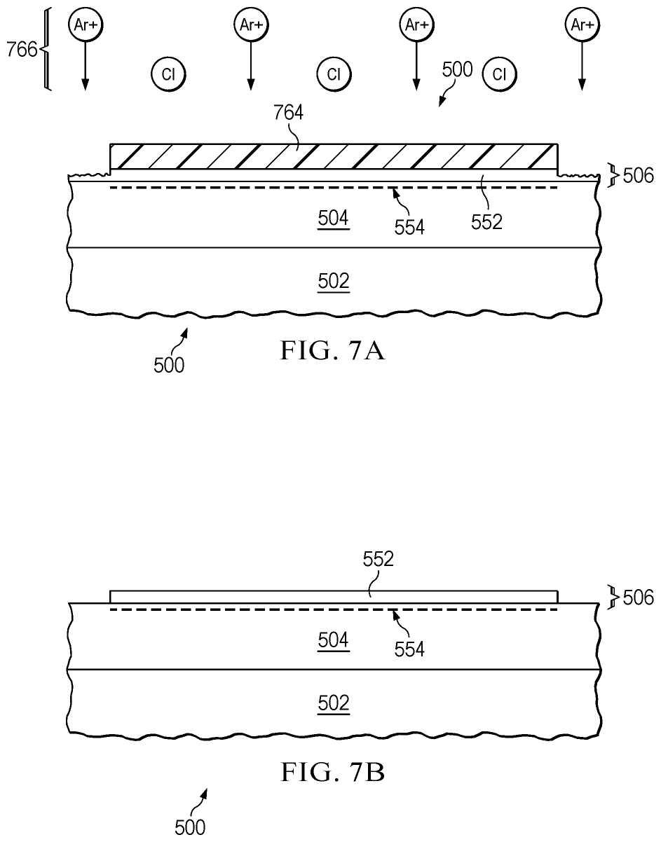

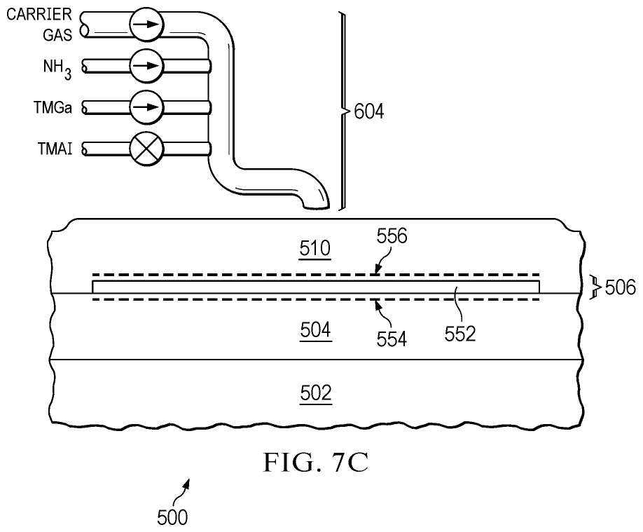

FIG. 7A through FIG. 7C are cross sections of the microelectronic device 500 of FIG. 5, depicted in an alternate example method of formation. Referring to FIG. 7A, after the buried barrier layer 552 is formed on the lower buffer layer 504, an etch mask 764 is formed over the buried barrier layer 552. The etch mask 764 covers an area of the buried barrier layer 552 for the screen layer 506 and exposes the buried barrier layer 552 outside of the area for the screen layer 506. The etch mask 764 may include photoresist, formed by a photolithographic process, and may include hard mask material such as silicon dioxide, formed by a PECVD process. Other compositions for the etch mask 764 are within the scope of this example.

The buried barrier layer 552 is removed where exposed by the etch mask 764 to localize the screen layer 506. The buried barrier layer 552 may be removed by a reactive ion etch (RIE) process 766 using a physical etchant species, depicted as argon ions, and a chemical etchant species, depicted schematically in FIG. 7A as neutral chlorine radicals. The RIE process 766 may be performed in an inductively coupled plasma (ICP) tool, which may provide independent control of the amount of the chemical etchant species and the energy of the physical etchant species, to advantageously adjust the etch rate of the buried barrier layer 552. FIG. 7A depicts the RIE process 766 partway to completion.

Referring to FIG. 7B, the etch mask 764 is removed after the buried barrier layer 552 is removed where exposed by the etch mask 764. The etch mask 764 may be removed by one or more removal processes similar to the removal processes disclosed in reference to removal of the implant mask 444 of FIG. 4A. Removal of the etch mask 764 leaves a sufficient thickness of the buried barrier layer 552 to provide a desired density of electrons in the screen layer 506.

Referring to FIG. 7C, the upper buffer layer 510 is formed on the buried barrier layer 552 and on the lower buffer layer 504 adjacent to the buried barrier layer 552 by the third MOVPE process 604. A top surface of the upper buffer layer 510 may have some topology due to step coverage of the buried barrier layer 552. The lower 2DEG layer 554 and the upper charge layer 556 of the screen layer 506 are localized to the area of the buried barrier layer 552, which may advantageously enable integration with other III-N components in the microelectronic device 500 would be compromised by the screen layer 506. Formation of the microelectronic device 500 continues with forming the barrier layer 516 of FIG. 5.

Various features of the examples disclosed herein may be combined in other manifestations of example microelectronic devices. For example, any of the microelectronic devices 100, 300, or 500 may include GaN FET pairs in half-bridge configurations, with the corresponding screen layer 106, 306 or 506 under at least the high side GaN FET. Any of the microelectronic devices 100, 300, or 500 may include standalone GaN FETs over the corresponding screen layer 106, 306 or 506. Any of the screen layer contacts may be combined with the source contacts or the drain contacts. Any of the screen layer contacts may be separate from the source contacts and the drain contacts. Any of the GaN FETs may be enhancement mode FETs, that is, normally off FETs. Any of the GaN FETs may be depletion mode FETs, that is, normally on FETs.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a silicon substrate;
a lower buffer layer of III-N semiconductor material over the silicon substrate;
a screen layer having free charge carriers over the lower buffer layer;
a field effect transistor having III-N semiconductor material over the screen layer; and
a screen contact electrically connected to the screen layer and to a current node of the field effect transistor.

2. The microelectronic device of claim 1, wherein the current node is a source of the field effect transistor.

3. The microelectronic device of claim 1, further including an upper buffer layer between the screen layer and the field effect transistor.

4. The microelectronic device of claim 1, wherein the screen layer includes a first conductivity type doped layer of III-N semiconductor material.

5. The microelectronic device of claim 1, wherein the screen layer includes a screen barrier layer of III-N semiconductor material on the lower buffer layer, the screen barrier layer having a higher band gap than the lower buffer layer contacting the screen barrier layer.

6. The microelectronic device of claim 5, wherein the screen barrier layer includes aluminum.

7. The microelectronic device of claim 1, wherein the screen layer extends completely over the lower buffer layer.

8. The microelectronic device of claim 1, wherein the field effect transistor is a high side transistor, and further including a low side transistor of III-N semiconductor material, wherein a drain of the low side transistor is electrically connected to a source of the high side transistor.

9. A method, comprising:
forming a screen layer including III-N semiconductor material over a lower buffer layer of III-N semiconductor material, the screen layer including free charge carriers.

10. The method of claim 9, further including:
forming a field effect transistor having III-N semiconductor material over the screen layer; and
forming a screen contact electrically connected to the screen layer and to a current node of the field effect transistor.

11. The method of claim 9, wherein the lower buffer layer is located over a silicon substrate.

12. The method of claim 9, further including forming an upper buffer layer over the screen layer.

13. The method of claim 9, wherein forming the screen layer includes forming a first conductivity type doped layer of III-N semiconductor material.

14. The method of claim 13, wherein forming the first conductivity type doped layer includes adding dopants during an epitaxial process.

15. The method of claim 14, wherein forming the first conductivity type doped layer includes implanting dopants into III-N semiconductor material of the doped layer.

16. The method of claim 15, further including forming an implant mask over the III-N semiconductor material of the first conductivity type doped layer, exposing the III-N semiconductor material in an area for the screen layer, and implanting the dopants into the III-N semiconductor material where exposed by the implant mask.

17. The method of claim 9, wherein forming the screen layer includes forming a screen barrier layer of III-N semiconductor material on the lower buffer layer, the screen barrier layer having a higher band gap than the lower buffer layer contacting the screen barrier layer.

18. The method of claim 17, wherein the screen barrier layer includes aluminum.

19. The method of claim 9, further including patterning the screen layer.

20. A method of forming a microelectronic device, comprising:
forming a field effect transistor having III-N semiconductor material over a screen layer, the screen layer having free charge carriers, the screen layer being located over a lower buffer layer of III-N semiconductor material over a silicon substrate; and
forming a screen contact electrically connected to the screen layer and to a current node of the field effect transistor.

21. The method of claim 20, wherein the field effect transistor is a high side transistor, and further including forming a low side transistor in III-N semiconductor material and forming an electrical connection from a drain of the low side transistor to a source of the high side transistor.
